(19) United States
(12) Patent Application Publication
(10) Pub. No.: US 2007/0065571 A1
(43) Pub. Date: Mar. 22, 2007

(54) Method and apparatus for manufacturing a pixel matrix of a color filter for a flat panel display

(75) Inventors: John M. White, Hayward, CA (US); Quanyuan Shang, Saratoga, CA (US); Yan Ye, Saratoga, CA (US); Ligui Zhou, Dublin, CA (US)

Correspondence Address: DUGAN & DUGAN, PC, 55 SOUTH BROADWAY, TARRYTOWN, NY, 10591, US

(73) Assignee: APPLIED MATERIALS. INC.

(21) Appl. No.: 11/521,577

(22) Filed: Sep. 13, 2006

Related U.S. Application Data
(60) Provisional application No. 60/718,565, filed on Sep. 19, 2005.
(60) Provisional application No. 60/834,076, filed on Jul. 28, 2006.

(51) Int. Cl. B05D 5/12; B05D 7/00; C08J 7/18; B05D 5/06; B05D 1/36; B05B 5/025; C23C 16/00; B05D 3/00

(52) U.S. Cl. 427/68; 427/402; 427/554; 118/620; 118/723 R

(57) ABSTRACT

Apparatus and methods are provided for forming a pixel matrix. The methods include coating a substrate with a pixel matrix material, coating the pixel matrix material with an ink-phobic material, and forming pixel wells in the pixel matrix material and the ink-phobic material. A system for forming a pixel matrix is provided that includes a patterning tool including a laser ablation system operable to form pixel wells in pixel matrix material coated with ink-phobic material. The laser ablation system is operable to form pixel wells in pixel matrix material coated with ink-phobic material in an oxygenated environment so that the sidewalls of the pixel matrix are made to be ink-philic. The invention also includes a pixel well structure in which the top surfaces of the pixel well is ink-phobic and the surfaces of the sidewalls are ink-philic. Numerous other aspects are provided.

The present application claims priority to U.S. Provisional Patent Application Ser. No. 60/718,565, filed Sep. 19, 2005 and entitled “METHOD AND APPARATUS FOR MANUFACTURING A PIXEL MATRIX OF A COLOR FILTER FOR A FLAT PANEL DISPLAY,” (Attorney Docket No. 10502/L) which is hereby incorporated herein by reference in its entirety for all purposes.

The present application claims priority to U.S. Provisional Patent Application Ser. No. 60/834,076, filed Jul. 28, 2006 and entitled “METHOD AND APPARATUS FOR MANUFACTURING A PIXEL MATRIX OF A COLOR FILTER FOR A FLAT PANEL DISPLAY,” (Attorney Docket No. 10502/L2) which is hereby incorporated herein by reference in its entirety for all purposes.

### CROSS-REFERENCE TO RELATED APPLICATIONS

The present application is related to the following commonly-assigned, co-pending U.S. patent applications, each of which is hereby incorporated herein by reference in its entirety for all purposes:

U.S. Provisional Patent Application Ser. No. 60/625,550, filed Nov. 4, 2004 and entitled “APPARATUS AND METHODS FOR FORMING COLOR FILTERS IN A FLAT PANEL DISPLAY BY USING INKJETTING”;

U.S. patent application Ser. No. 11/019,967, filed Dec. 22, 2004 and entitled “APPARATUS AND METHODS OF AN INKJET HEAD SUPPORT HAVING AN INKJET HEAD CAPABLE OF INDEPENDENT LATERAL MOVEMENT” (Attorney Docket No. 9521-1);

U.S. patent application Ser. No. 11/019,929, filed Dec. 22, 2004 and titled “METHODS AND APPARATUS FOR INKJET PRINTING.” (Attorney Docket No. 9521-2);

U.S. patent application Ser. No. 11/019,930, filed Dec. 22, 2004 and entitled “METHODS AND APPARATUS FOR ALIGNING PRINT HEADS” (Attorney Docket No. 9521-3);

U.S. Provisional Patent Application Ser. No. 60/703,146, filed Jul. 28, 2005 and entitled “METHODS AND APPARATUS FOR SIMULTANEOUS INKJET PRINTING AND DEFECT INSPECTION” (Attorney Docket No. 9521-L02 (formerly 9521-7/L); and

U.S. patent application Ser. No. 11/493,861, filed Jul. 25, 2006 and entitled “METHODS AND APPARATUS FOR CONCURRENT INKJET PRINTING AND DEFECT INSPECTION” (Attorney Docket No. 9521-10)

### FIELD OF THE INVENTION

The present invention relates generally to inkjet printing for flat panel display manufacturing, and is more particularly concerned with apparatus and methods for forming a pixel matrix on a substrate.

### BACKGROUND

The flat panel display industry has been attempting to employ inkjet printing to manufacture display devices, and in particular, color filters for flat panel displays. Because the pixel wells into which ink is deposited when printing patterns for color filters may be particularly small, the possibility of defects is significant. Thus, improved methods and apparatus, including improved pixel matrix structures, to aid in accurately and consistently depositing ink into pixel wells are needed.

### SUMMARY OF THE INVENTION

In certain aspects of the invention, a pixel matrix is provided including a plurality of pixel wells, each pixel well including a top surface and a sidewall surface, wherein the top surface is ink-phobic and the sidewall surface is ink-philic.

In other aspects of the invention, a system for forming a pixel matrix is provided that includes a patterning tool including a laser ablation system operable to form pixel wells in pixel matrix material coated with ink-phobic material. The laser ablation system is operable to form pixel wells in pixel matrix material coated with ink-phobic material in an oxygenated environment so that the sidewalls of the pixel matrix are made to be ink-philic.

In yet other aspects of the invention, a method of forming a pixel matrix is provided including printing a pixel matrix by depositing a plurality of beads of pixel matrix material on a substrate in a matrix pattern, and laser ablating a portion of each bead of pixel matrix material to form vertical sidewall surfaces.

In still other aspects of the invention, a method of forming a pixel matrix is provided that includes coating a substrate with a pixel matrix material, coating the pixel matrix material with an ink-phobic material, and forming pixel wells in the pixel matrix material and the ink-phobic material.

Other features and aspects of the present invention will become more fully apparent from the following detailed description, the appended claims and the accompanying drawings.

### BRIEF DESCRIPTION OF THE DRAWINGS

FIG. 1 is a depiction of drops on a substrate with various degrees of wettability.

FIG. 2 is a depiction of a close up, cross-sectional view of a pixel well with ink deposited on the top surface of the pixel matrix material.

FIGS. 3 and 4A through 4C are depictions of close up, cross-sectional views of pixel wells according to embodiments of the present invention.

FIGS. 5A and 5B are schematic depictions of top and cross-sectional side views respectively of a substrate being processed according to a first step of example methods of the present invention.

FIGS. 6A and 6B are schematic depictions of top and cross-sectional side views respectively of a substrate being processed according to a second step of example methods of the present invention.

FIGS. 7A and 7B are schematic depictions of top and cross-sectional side views respectively of a substrate being processed according to a third step of example methods of the present invention.

FIG. 8 is a flowchart depicting an example method according to some embodiments of the present invention.

FIGS. 9 and 10 are schematic cross-sectional views of two example embodiments of patterning tools according to the present invention.

### DETAILED DESCRIPTION

The present invention provides systems, methods, and apparatus that allow formation of a pixel matrix on a substrate in which the top surfaces of the pixel matrix material (e.g., black matrix material) are ink-phobic while the side wall surfaces of the pixel matrix material are ink-philic. This novel structure results in improved color filters for flat panel displays (e.g., LCD, OLED, etc.) because any ink inadvertently deposited on the ink-phobic pixel matrix material top surface will tend to flow off into the pixel wells while ink in the pixel wells will not tend to bead away from the ink-philic pixel well sidewall surfaces, as is the case with pixel matrices manufactured entirely with ink-phobic material. The novel structure is achieved by layering an ink-phobic coating on top of a solid, ink-phillic layer of pixel matrix material on a substrate. A laser ablation system is used in an oxygenated environment to directly pattern a pixel matrix out of the coated solid layer of pixel matrix material. Laser ablation in an oxygenated environment results in charring the pixel matrix material on the formed pixel well sidewalls which makes the sidewalls more ink-phillic, while the top surface of the matrix remains ink-phobic due to the ink-phobic coating.

Materials in contact with liquid may have an attractive or repulsive response to the liquid. The material's composition, its corresponding surface chemistry, and the chemistry of the liquid determine the interaction with the liquid. This phenomena is termed hydrophilicity (e.g., ink-philicity for liquid ink) and hydrophobicity (e.g., ink-phobicity for liquid ink).

Hydrophilicity, also called hydrophilic, is a characteristic of materials exhibiting an affinity for liquid. Hydrophilic literally means “liquid-loving” and such materials readily adsorb liquids. The surface chemistry allows these materials to be wetted forming a liquid film or coating on their surface. Hydrophilic materials also possess a high surface tension value and have the ability to form bonds with liquid.

Hydrophobicity, also termed hydrophobic, materials possessing this characteristic have the opposite response to liquid interaction compared to hydrophilic materials. Hydrophobic materials (“liquid fearing”) have little or no tendency to adsorb liquids and liquid tends to “bead” on their surfaces (i.e., form discrete droplets). Hydrophobic materials possess low surface tension values and lack active groups in their surface chemistry for formation of bonds with liquid.

Wettability refers to a surface property characteristic for materials. The surface tension value of a material can be utilized to determine wettability of a material by specific liquids. Through the measurement of the contact angle θ between a solid surface and a droplet of liquid on the surface, the surface tension for the solid material can be calculated.

Surface tension refers to a force, due to an unbalance in molecular forces that occurs when two different materials (e.g., a liquid droplet on a solid surface) are brought into contact with each other forming an interface or boundary. The force is due to the tendency for all materials to reduce their surface area in response to the unbalance in molecular forces that occurs at their points of contact. The result of this force will vary for different systems of liquids and solids, which dictates the wettability and contact angle between the drop and surface.

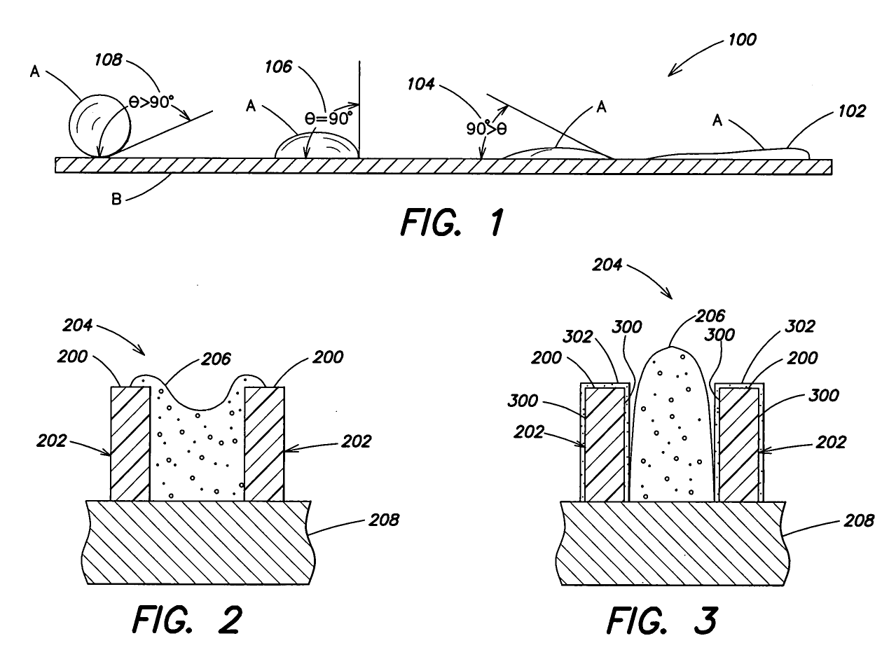

Turning to FIG. 1, a continuum of wettability 100 is depicted. For a given droplet A on a solid surface B the contact angle θ is a measurement of the angle formed between the surface of a solid B and the line tangent to the droplet A radius from the point of contact with the solid B. The contact angle θ is related to the surface tension by Young's equation through which the behavior of specific liquid-solid interactions can be calculated. A contact angle θ of zero degrees 102 results in wetting, while an angle θ between zero and ninety degrees 104 results in spreading of the drop (due to molecular attraction). A contact angle θ of ninety degrees 106 may result in steady state in which the surface tension stops the spreading of the liquid. Angles θ greater than ninety degrees 108 indicate that the liquid tends to bead or shrink away from the solid surface.

Flat panel display manufacturing may use color filters that include different colored inks printed on a glass (or other material) substrate. The ink may be deposited using an inkjet printer adapted to precisely jet ink and/or other suitable material directly into specific pixel wells defined by a matrix. Before the ink is deposited, the matrix of pixel wells may be formed on the on the substrate using lithography, printing, or any other suitable process. Due to variations in the ink-philicity/ink-phobicity of the substrate and/or the material used to form the matrix, the cross-sectional fill profile (e.g., the distribution) of the ink drops deposited into the pixel wells may not be optimal for forming color filters. In some cases, the uneven distribution of ink within a pixel well may result in a defect in the color filter. For example, if the ink “beads-up,” it may not fill the pixel wells completely. The inventors of the present invention have noticed that the ink-philicity/ink-phobicity of the matrix varies significantly among manufactures. Attempts to adjust the surface tension and thus, the fill profile of the ink through chemical variations, if even possible, may not be satisfactory.

Referring to FIG. 2, the present inventors have further noticed that the top (e.g., horizontal (during color filter printing)) surface 200 of the materials 202 typically employed to form a pixel matrix 204 (e.g., black matrix) may be sufficiently ink-philic such that ink 206 meant to land within the pixel wells 204 tends to wet the top surface 200 if the ink 206 lands on the pixel matrix 204 and undesirably remains on the top surface 200. Further, the profile of the ink 206 within a pixel well 204 on a substrate 208 may be undesirably concave due to ink 206 remaining on the top 200 of the ink-philic pixel matrix material 202 as shown in the cross-sectional view of a pixel well 204 in FIG. 2. In some embodiments, unlike FIG. 2, it may be desirable that the top surface of the ink filled pixel wells is flat and flush with the top surface of the pixel matrix walls.

As shown in FIG. 3, one approach to compensate for this problem has been to treat or coat all the surfaces (including the top 200 and sides 300) of the pixel matrix material 202 to make the surfaces ink-phobic before ink 206 is deposited within the pixel wells 204. The idea was that by applying the coating 302, the pixel matrix material 202 may be made more resistant to ink 206 spreading on the top surface. The treating or coating 302 is done after the pixel matrix 204 has been patterned and, as indicated, before the wells are filled with ink 206. While such treatments or coatings 302 may make the top surface 200 less prone to ink spreading, the sidewalls 300 of the pixel wells 204 may become too ink-phobic and the profile of ink 206 deposited in the wells 204 may be convex to an undesirable degree due to the ink drawing away from the ink-phobic pixel well walls 204 as shown in FIG. 3.

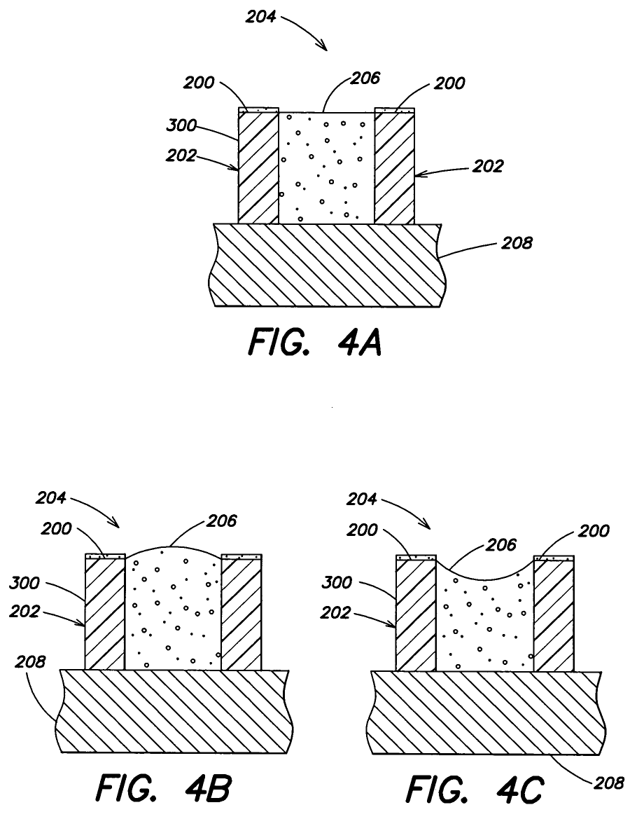

Turning to FIGS. 4A through 4C, the present invention provides systems, methods, and apparatus that allow formation of a pixel matrix 204 in which the top surfaces 200 of the pixel matrix material 202 are ink-phobic while the side wall surfaces 300 of the pixel matrix material 202 are ink-philic. When the top surface 200 of the pixel matrix material 200 is ink-phobic and the sidewalls 300 are ink-philic, the ink 206 will fill the pixel matrix 204 to an ideal level if the correct amount of ink 206 is dispensed as depicted in FIG. 4A. If the amount of ink 206 that's dispensed is slightly more than ideal, the ink-phobic top 200 and ink-philic sidewalls 300 will still be able to provide the most ideal shape (e.g., convex from the tops of sidewall to sidewall) possible (given the circumstances) for the surface of the ink 206 as depicted in FIG. 4B. If the amount of ink 206 that's dispensed is slightly less than ideal, the ink-phobic top 200 and ink-philic sidewalls 300 will still be able to provide the most ideal shape (e.g., concave from the tops of sidewall to sidewall) possible (given the circumstances) for the surface of the ink 206 as depicted in FIG. 4C.

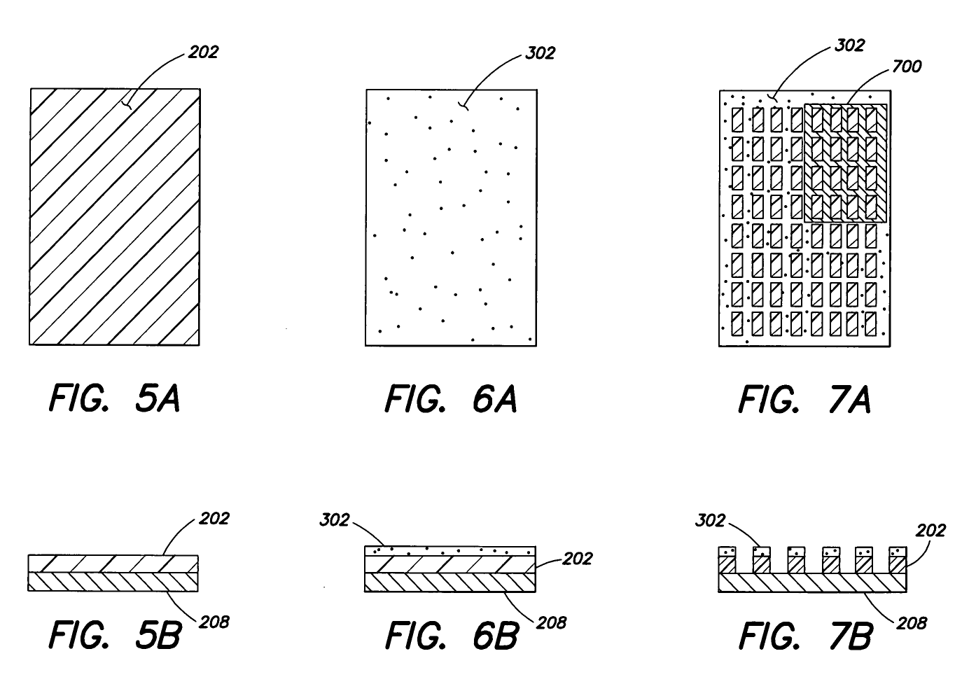

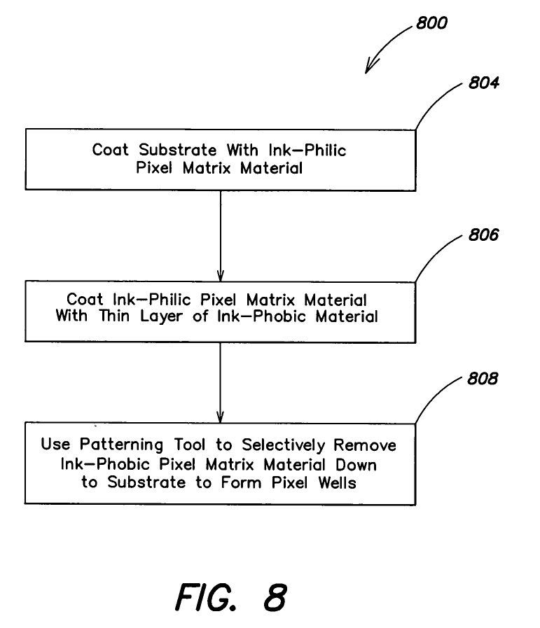

A method of manufacturing a pixel matrix according to some embodiments of the present invention is now described with reference to FIGS. 5A through 8. The method 800 is depicted as a flow chart in FIG. 8.

In step 804, the substrate 208 is first coated with a layer of pixel matrix material 202 (e.g., a polymer) as shown in the top and side views of a substrate in FIGS. 5A and 5B, respectively. The pixel matrix material layer 202 may be between about 1 micron thick and 2.5 microns thick. Other thickness ranges are possible. The pixel matrix material layer 202 is selected to be relatively ink-philic to the ink that will later be used to fill the pixel wells.

Next in step 806, as shown in the top and side views of a substrate 208 in FIGS. 6A and 6B, the surface of the pixel matrix material layer 202 is treated or coated with a very thin layer of very highly ink-phobic material 302 between about 10 Å and 1000 Å thick. Other thickness ranges are possible.

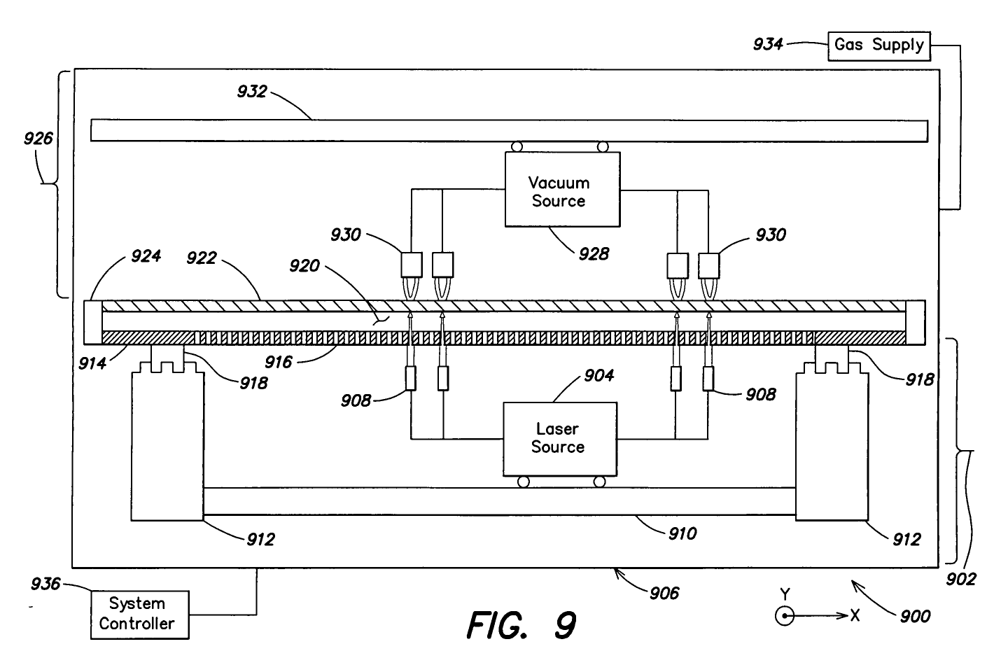

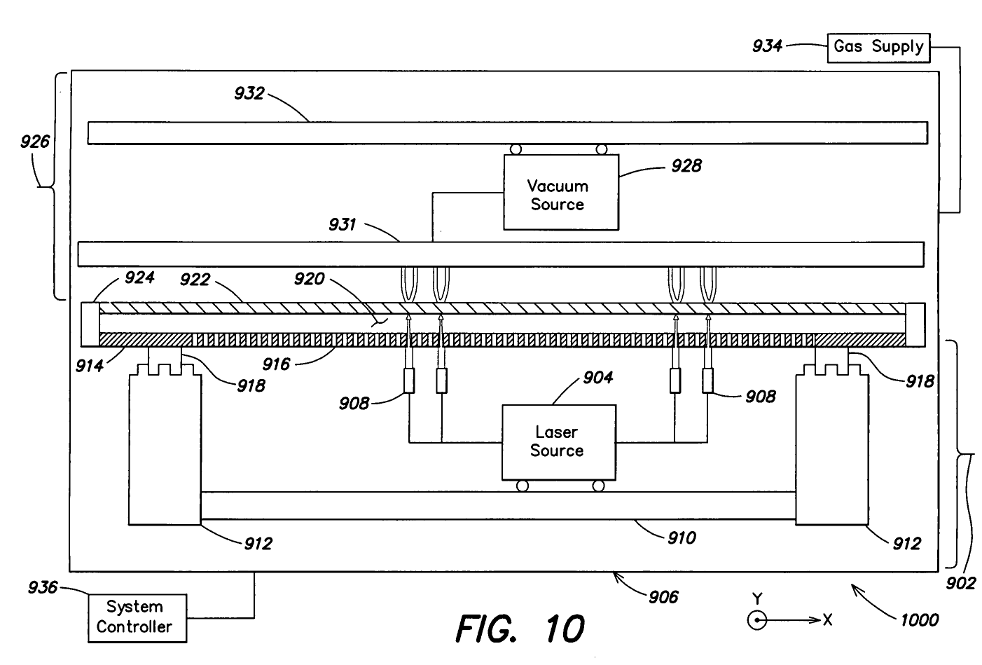

In a subsequent step 808, as depicted in FIGS. 7A and 7B, a direct-patterning tool 700 such as a laser ablation system is used to selectively remove portions of the treated or coated pixel matrix material layer 202 completely down to the substrate 208, creating the pixel “inkwells” or “wells.” A laser ablation system is described in detail below with respect to FIGS. 9 and 10. The patterned substrate 208 is then ready for ink filling. The sidewalls of the wells are thus as ink-philic as the bulk material used to form the pixel matrix material layer 202 and the top is left ink-phobic due to the treatment or coating 302. Note that the figures are not to scale.

In some embodiments of the present invention, pixel matrix material may be selected which is relatively ink-phobic to the ink that will later be used to fill the pixels. The laser ablation (patterning) step 808 may then be performed in an oxygenated environment. The effect of the oxygen will be to cause a “burning” or charring of the sidewalls of the pixel wells which causes the sidewalls to become relatively ink-philic while the top surface of the pixel matrix remains ink-phobic. In such an alternative method, the step 804 of coating the pixel matrix material with ink-phobic material may be omitted.

The above methods use a laser ablation system to create the novel pixel matrix structure of the present invention. However, in other embodiments, methods that do not use laser ablation may be utilized to create the novel structure of the present invention. For example, a photoresist pixel matrix polymer material may be layered on a substrate, treated with an ink-phobic material, and then patterned using lithography.

Once the novel structure described above has been formed on a substrate, an ink jet printing system as described, for example, in previously incorporated US patent application U.S. Provisional Patent Application Ser. No. 60/625,550 may be used to fill the pixel matrix with colored inks to form a color filter suitable for use in a flat panel display. In some embodiments, after ink filling, it may be desirable to apply a clear coating (e.g., transparent electrode, indium-tin oxide (ITO)) in a level, even layer above the ink filled pixel matrix. However, if the top surfaces of the pixel matrix remain ink-phobic, it may be difficult to evenly distribute the clear coating. In such embodiments, a solution of hydrocarbons, fluorinated hydrocarbons, and/or chlorinated silicon oil may be first flowed over the ink filled pixel matrix to make the top surface consistent in terms of ink or other liquid philicity.

In yet another alternative embodiment of the present invention, the pixel matrix may be printed on the substrate using a material that cures to be ink-phobic. Ink jetting pixel matrix material may be performed so that the material is deposited in a half-moon, bead shape. In some embodiments, both sides of the half-moon shaped bead of printed pixel matrix material may be trimmed to create vertical sidewalls using laser ablation in an oxygenated environment. The sidewalls will thus be burned so that they become ink-philic as a result of the laser ablation.

The present invention further includes a patterning tool 900, 1000 as shown in the example embodiments of FIGS. 9 and 10, respectively. Referring to FIG. 9, a cross-sectional schematic representation of a patterning tool 900 is depicted. The patterning tool 900 includes a laser ablation system 902 which includes one or more laser sources 904 disposed within an enclosure 906. The laser sources 904 may include, or be coupled to, one or more optics heads 908. The laser sources 904 and/or the optics heads 908 may be supported by a laser bridge 910. Although not shown, the laser bridge 910 may also include a system of motors, actuators, drivers, gears, linkages, and other components adapted to effect operation of the laser bridge 910 as described below. The laser bridge 910 may be supported by a tool base 912. The tool base 912 may be made, for example, from large granite blocks and include vibration isolation features.

The patterning tool 900 may also include a moveable stage 914 (e.g., an X-Y table) that may include or support an optional mask 916. The stage 914 may be supported by a rail system 918 on the tool base 912. The stage 914 is adapted to support a substrate 920 coated with pixel matrix material 922. The stage 914 is adapted to support the substrate 920 so that it remains flat and close to the optics heads 908 which are disposed below the substrate 920. The stage 914 may also include a chucking system 924 for holding the substrate 920 in place on the stage 914. Although not shown, the stage 914 may also include a system of motors, actuators, drivers, gears, linkages, and other components adapted to effect operation of the stage 914 as described below.

The patterning tool 900 may also include a waste removal system 926 that may include a vacuum source 928 coupled to one or more extraction heads 930. The vacuum source 928 and/or the extraction heads 930 may be supported by a gantry 932 which may be suspended by vertical members (not shown) that are supported by the tool base 912. Although not shown, the gantry 932 may also include a system of motors, actuators, drivers, gears, linkages, and other components adapted to effect operation of the gantry 932 as described below. The tool 900 may also include or be coupled to a gas supply 934 adapted to supply oxygen or other gas to the enclosure or to flow the oxygen directly to the area being ablated (e.g., via one or more conduits not shown). The tool 900 may operate under the direction of a system controller 936 which may include a user interface (not shown) and/or a manufacturing execution system interface (not shown).

Turning to FIG. 10, an alternative patterning tool 1000 example embodiment is depicted that is similar to the above described tool 900 except instead of multiple extraction heads 930, the alternative patterning tool 1000 includes a suction vent 931 that spans across all the areas of the substrate 920 that are being ablated.

Referring to both FIGS. 9 and 10, in operation, the patterning tool 900, 1000 forms pixel wells in the pixel matrix material 922 on the substrate 920. The laser source 904 (e.g., a diode pumped solid state (DPSS) laser) is operative to perform precision ablative patterning of pixel matrix material 922 (e.g., black matrix resin). For example, multiple high power CW Q switched DPSS lasers (e.g., operating at 1.06 μm wavelength, 350 W of power at 10 kHz, 30 kHz Max rep rate, and approximately 80 ns pulse length at 10 kHz) may be used to deliver energy via fibre to the optics heads 908.

Substrates 920 of any size may be hand or machine loaded onto the stage 914 where the substrate 920 is secured by the chucking system 924. The stage 914 is operative to move on one axis above the laser bridge 910 which is adapted to move optics heads 908 and/or the laser source 904 along a second, orthogonal axis. In some embodiments, an imaging system (e.g., a CCD camera) (not shown) may be provided to inspect the substrate 920 and/or aid in the alignment of the substrate 920 using fiducial marks on the substrate 920.

Once a substrate 920 has been loaded onto the stage 914, the optics heads 908 may direct laser energy through apertures in the mask 916 (if used), up through the substrate 920 (which does not absorb a significant amount of laser energy), and into the layer of pixel matrix material 922. Oxygen, concurrently flowed into the tool 900, 1000 via the gas supply 934, in combination with the laser energy volatizes the pixel matrix material 922 exposed to the laser energy through the mask 916. Debris material is removed by the extraction heads 930 or the suction vent 931.

The stage 914 is operative to move the substrate 920 in the ±Y-directions (e.g., the direction into and out of the surface of the page upon which the figure is drawn indicated by the outward pointing arrowhead “⊙” labeled Y). The optics heads 908 and/or the laser source 904 are adapted to be moved in the ±X-directions (as indicated by the arrow labeled X) along the laser bridge 910. Likewise, the vacuum source 928 and/or the extraction heads 930 are adapted to be moved in the ±X-directions along the gantry 932 to positions that correspond to the locations of the optics heads 908 and/or the laser source 904. Note that the suction vent 931 may not need to be moved at all because the suction vent 931 spans across the substrate 920.

The motions and operation of the stage 914, the gas supply 934, the optics heads 908, the laser source 904, the vacuum source 928, and/or the extraction heads 930 may be under the control of the system controller 936. The system controller 936 may direct the components of the tool 900, 1000 to move in a desired pattern while ablating selected portions of the pixel matrix material 922 from the substrate 920 to form a pixel matrix. In some embodiments, a mask 916 may not be used and instead, the system controller 936 may direct the optics heads 908 and/or the laser source 904 when to activate and direct the laser bridge 910 and stage 914 when and where to move the optics heads 908 (and/or the laser source 904) and the substrate 920, respectively.

The foregoing description discloses only particular embodiments of the invention; modifications of the above disclosed methods and apparatus which fall within the scope of the invention will be readily apparent to those of ordinary skill in the art. Further, the present invention may also be applied to spacer formation, polarizer coating, and nanoparticle circuit forming.

Accordingly, while the present invention has been disclosed in connection with specific embodiments thereof, it should be understood that other embodiments may fall within the spirit and scope of the invention, as defined by the following claims.

The invention claimed is:

1. A method of forming a pixel matrix comprising:
coating a substrate with a pixel matrix material;
coating the pixel matrix material with an ink-phobic material; and
forming pixel wells in the pixel matrix material and the ink-phobic material.

2. The method of claim 1 wherein the substrate is glass suitable for use in manufacturing a color filter for a flat panel display.

3. The method of claim 1 wherein the substrate is coated with a pixel matrix material that is ink-philic.

4. The method of claim 1 wherein the substrate is coated with a pixel matrix material having a thickness suitable for forming pixel wells.

5. The method of claim 1 wherein the pixel matrix material is coated with a layer of ink-phobic material that is thin relative to a thickness of the pixel matrix material.

6. The method of claim 1 wherein forming pixel wells includes forming the pixel wells such that a top surface of the pixel wells is ink-phobic and side surfaces of the pixel wells are ink-philic.

7. The method of claim 1 wherein forming pixel wells includes patterning a pixel matrix using laser ablation.

8. The method of claim 7 wherein patterning a pixel matrix using laser ablation includes using laser ablation in an oxygenated environment.

9. The method of claim 8 wherein laser ablating in an oxygenated environment causes formation of pixel well sidewalls that are ink-philic.

10. The method of claim 9 wherein a top surface of the pixel wells is ink-phobic due to the ink-phobic coating.

11. The method of claim 7 wherein a laser source disposed below the substrate is used to ablate, through the substrate, the coating of the pixel matrix material disposed on a top surface of the substrate.

12. A method of forming a pixel matrix comprising:
coating a substrate with an ink-phobic pixel matrix material; and
forming pixel wells in the pixel matrix material using laser ablation in an oxygenated environment to directly pattern the pixel wells,
wherein the pixel wells are formed such that a top surface of the pixel wells is ink-phobic and sidewall surfaces of the pixel wells are ink-phillic.

13. A system for forming a pixel matrix comprising:
a patterning tool including a laser ablation system operable to form pixel wells in pixel matrix material on a substrate,
wherein the laser ablation system is operable to form the pixel wells with an ink-phobic top surface and ink-phillic sidewall surfaces.

14. The system of claim 13 wherein the laser ablation system is operable to form pixel wells in pixel matrix material coated with ink-phobic material.

15. The system of claim 13 wherein the laser ablation system is operable to form pixel wells in pixel matrix material in an oxygenated environment.

16. The system of claim 13 wherein the patterning tool includes a vacuum system adapted to remove materials volatilized by the laser ablation system.

17. The system of claim 13 wherein the patterning tool includes a mask through which the laser ablation system volatizes the pixel matrix material to form a matrix of pixel wells.

18. The system of claim 13 wherein the laser ablation system is operable to form pixel wells in pixel matrix material coated with ink-phobic material using at least one laser disposed below the substrate,
wherein the laser ablation system includes an enclosure and an oxygen supply and is operable to form pixel wells in pixel matrix material in an oxygenated environment,
wherein the patterning tool includes a vacuum system disposed above the substrate and adapted to remove materials as the materials are volatilized by the laser ablation system, and
wherein the patterning tool includes a mask disposed between the laser and the substrate, and through which the laser ablation system volatizes the pixel matrix material to form a matrix of pixel wells.

19. A method of forming a pixel matrix comprising:
printing a pixel matrix by depositing a plurality of beads of pixel matrix material on a substrate in a matrix pattern; and
laser ablating a portion of each bead of pixel matrix material to form vertical sidewall surfaces.

20. The method of claim 19 wherein the substrate is glass suitable for use in manufacturing a color filter for a flat panel display.

21. The method of claim 19 wherein the pixel matrix material is ink-phobic.

22. The method of claim 19 wherein the deposited beads of pixel matrix material has a height suitable for forming pixel wells.

23. The method of claim 19 wherein laser ablating a portion of each bead of pixel matrix material includes laser ablating a portion of each bead of pixel matrix material in an oxygenated environment to form ink-philic sidewall surfaces.

24. A pixel matrix comprising:
a plurality of pixel wells, each pixel well including a top surface and a sidewall surface,
wherein the top surface is ink-phobic, and
wherein the sidewall surface is ink-philic.

25. The pixel matrix of claim 24 wherein the pixel wells are formed on a substrate and the pixel matrix is adapted to receive ink to form a color filter.

26. The pixel matrix of claim 24 wherein the pixel wells are formed on a substrate by laser ablating a pixel well pattern in a top layer of black matrix material on the substrate using a laser source disposed below the substrate and directed through the substrate.

27. The pixel matrix of claim 26 wherein the pixel wells are formed on a substrate using a patterning mask disposed between the laser source and the substrate.

28. The pixel matrix of claim 24 wherein the pixel wells are formed on a substrate by lithography.
